(19) United States
(12) Patent Application Publication
(10) Pub. No.: US 2002/0000612 A1
(43) Pub. Date: Jan. 3, 2002

(54) POWER-MOS TRANSISTOR

(76) Inventor: JAMES R. TODD, PLANO, TX (US)

Correspondence Address: TEXAS INSTRUMENTS INCORPORATED, P O BOX 655474, M/S 3999, DALLAS, TX, 75265

(21) Appl. No.: 09/212,186

(22) Filed: Dec. 15, 1998

Related U.S. Application Data
(60) Provisional application No. 60/068,127, filed on Dec. 19, 1997.

(51) Int. Cl. H01L 31/119; H01L 31/113

(52) U.S. Cl. 257/341

(57) ABSTRACT

A semiconductor device (10) is provided that comprises a substrate (12) having a first conductivity type. An epitaxial layer (14) of a second conductivity type is formed outwardly from the substrate (12). An isolation region (16) is formed in the epitaxial layer (14) and the substrate (12). A guard ring (18) is formed in portions of the substrate (12) and portions of the epitaxial layer (14). An active region (20) of the second conductivity type is defined in the epitaxial layer (14) by the isolation region (16) and the guard ring (18). A gate body (24, 26) is insulatively disposed outwardly from the active region (20). An insulative structure (32) having a plurality of contact openings (34) and (36) is disposed outwardly from the gate body (24, 26) and the epitaxial layer (14). A conductive interconnect layer (38) is disposed outwardly from the insulative structure (32) and fills the contact openings (34) and (36). The conductive interconnect layer (38) is etched to form source and drain interconnects (40) and (42). A planarization layer (44) is formed outwardly from the conductive interconnect layer (38) and has an planarization contact opening (48). A passivation layer (46) is formed outwardly from the planarization layer (44) and has a passivation contact opening (48). A conductive layer (50) is formed outwardly from the passivation layer (46). The conductive layer (50) contacts the conductive interconnect layer (38) through the passivation contact opening (48) and planarization contact opening (48). The conductive layer (50) is electrically isolated from the conductive interconnect layer (38) by the planarization layer (44) and the passivation layer (46).

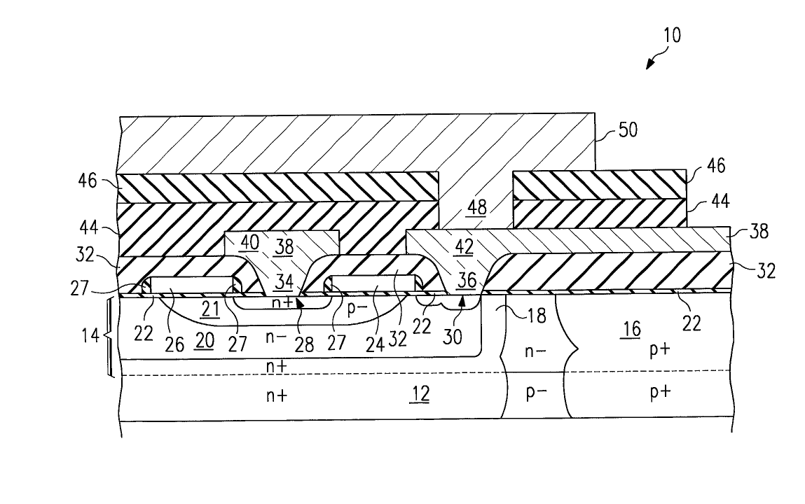

### BACKGROUND OF THE INVENTION

Solid state devices used to provide power for motors and RF devices are often implemented using field effect transistors. These power transistors comprise relatively large gate bodies that are interdigitated between source and drain regions. The power transistor structure must provide for high current switching capability. A power transistor structure also requires large voltage drops between the drain and the source and between the drain and the gate when the transistor is off and the gate is at source potential.

Present systems have provided power transistors with adequate current carrying capability at adequate voltage ranges. Isolation of the power transistor from neighboring electronic devices is traditionally provided for by the addition of a moat module that includes the growth of a field oxide and channel stop implants to prevent the formation of surface parasitic MOS devices. The moat module involves considerable processing time and procedures to complete.

Present power transistor devices also utilize three layers of metallization with the outermost layer having a low resistivity to minimize the metal bus resistance. A first layer of metallization is provided to form conductive interconnects to the source and drain regions of the device. A second layer of metallization is provided to form both a source bus and a drain bus and to contact the source and drain interconnects. However, the second layer of metallization alone is inadequate as a drain bus or a source bus to provide the high current switching capability necessary for power transistor devices. An outermost level of conductive material, copper for example, is therefore provided to increase the effective thickness of drain and source bus layers, thereby decreasing the bus resistance and minimizing IR drops along the bus.

The processing of the isolation moat module combined with the necessity for three layers of metallization increase processing time, difficulty and expense associated with the production of power transistor devices.

### SUMMARY OF THE INVENTION

Accordingly, a need has arisen for a field effect device that can provide the traditionally necessary high current-carrying capability with relatively high breakdown voltages, but which does not require the additional processing time and expense needed to create field oxide structures in most isolation schemes or require the introduction of an intermediate level of metallization.

In accordance with the teachings of the present invention, a semiconductor device is provided that comprises a substrate having a first conductivity type. An epitaxial layer of a second conductivity type is formed outwardly from the substrate. An isolation region is formed in the epitaxial layer and the substrate. A guard ring is formed in portions of the substrate and portions of the epitaxial layer. An active region of the second conductivity type is defined in the epitaxial layer by the isolation region and the guard ring. A gate body is insulatively disposed outwardly from the active region. An insulative structure having a plurality of contact openings is disposed outwardly from the gate body and the epitaxial layer. A conductive interconnect layer is disposed outwardly from the insulative structure and fills the contact openings. The conductive interconnect layer is etched to form source and drain interconnects. A planarization layer is formed outwardly from the conductive interconnect layer and has an planarization contact opening. A passivation layer is formed outwardly from the planarization layer and has a passivation contact opening. A conductive layer is formed outwardly from the passivation layer. The conductive layer contacts the conductive interconnect layer through the passivation contact opening and planarization contact opening. The conductive layer is electrically isolated from the conductive interconnect layer by the planarization layer and the passivation layer.

The disclosed invention offers many technical advantages. For example, the invention provides an electronic device that is isolated from neighboring devices without the need for complex field oxide isolation structures and channel stop implants, saving time and processing steps. In addition, the invention optimizes the process of fabricating an electronic device by eliminating the use of an intermediate metal interconnect layer. In particular, the disclosed invention allows the construction of high voltage power transistors using copper without the need for three separate layers of metallization within a single device. Other technical advantages will be readily apparent to one skilled in the art from the following figures, descriptions, and claims.

### BRIEF DESCRIPTION OF THE DRAWINGS

A more complete understanding of the invention may be acquired by referring to the accompanying figures in which like reference numbers indicate like features and wherein:

The FIGURE is a schematic cross-sectional diagram of one embodiment of a power transistor according to the teachings of the present invention.

### DETAILED DESCRIPTION OF THE INVENTION

The preferred embodiments of the present invention and its advantages are best understood by referring to the FIGURE of the drawings, like numerals being used for like and corresponding parts of the drawings.

The FIGURE illustrates an embodiment of the structure of a power field effect transistor according to the teachings of the present invention. Semiconductor device 10 includes a P− substrate 12. In one embodiment, substrate 12 is a wafer formed from a single crystalline silicon material. It will be understood that substrate 12 may comprise other materials and/or layers within the scope of the present invention. For example, substrate 12 may comprise an epitaxial material, a recrystallized semiconductor material, a polycrystalline semiconductor material, or other suitable materials. In one embodiment, substrate 12 is a P-type substrate comprising, for example, boron.

The outer surface of substrate 12 is provided with N+ diffused regions (not shown), using implanted dopants of antimony, and P+ diffused regions (not shown), using implanted dopants of Boron, prior to the growth of an N-epitaxial layer 14 of approximately 15 microns in thickness. N− epitaxial layer 14 is comprised of, for example, phosphorus. After the growth of N− epitaxial layer 14, the buried N+ diffused regions migrate upwards into epitaxial layer 14, approximately 8 microns, for example. The N+ and P+ diffused regions are then augmented by diffusions from the outer surface of epitaxial layer 14, to provide for a P+ isolation region 16, comprising boron, and an N+ guard ring 18, comprising antimony.

Isolation region 16 and guard ring 18 isolate and define an active region 20 of about 6 microns in thickness in which the power transistor of the present invention is formed.

A gate insulator layer 22 is grown outwardly from surface of substrate 12. Gate insulator layer 22 may be on the order of 525 angstroms in thickness. Gate insulator layer 22 comprises, for example, silicon dioxide. It will be understood that gate insulator layer 22 may comprise another type of material capable of insulating semiconductor elements.

Gate bodies 24 and 26 are disposed outwardly from gate insulator layer 22 over active region 20. Gate bodies 24 and 26 may be, for example, on the order of 5000 Angstroms in thickness. Gate bodies 24 and 26 may be disposed with a distance of 3.5 microns between them, for example. Gate bodies 24 and 26 may be approximately 2.5 microns in width. Gate bodies 24 and 26 comprise polycrystalline silicon, or other suitable material including single crystalline silicon or gallium arsenide.

Following the formation of gate bodies 24 and 26, a P− well 21 is formed by implanting boron dopants between gate bodies 24 and 26 and then diffusing the dopants until P-well 21 reaches a width of approximately 7.5 microns. P-well 21 does not extend beyond the far outside walls of gate bodies 24 and 26.

Gate sidewalls 27 may then be formed, for example, by depositing one or more conformal layers of TEOS (tetra-ethyl-ortho-silicate) oxide over the transistor utilizing a chemical vapor deposition (CVD) process. The conformal layer or layers of TEOS oxide may then be anisotropically etched, leaving gate sidewalls 27 formed at a width of 3,000 Angstroms, for example.

Within active region 20, highly-diffusible dopants may be implanted and diffused into a conductive source region 28, within P− well 21, and a conductive drain region 30, outside of P− well 21. Conductive source region 28 and conductive drain region 30 may be spaced opposite one another and apart from gate body 24 to define a channel region in active region 20.

Plate shielding (not explicitly shown) is used, instead of the channel stop implants and field isolation structures normally used to isolate MOS devices, to prevent the formation of parasitic MOS devices. Plate shielding results from gate bodies 24 and 26 completely surrounding all P diffusions present in active region 20. For example, gate bodies 24 and 26 completely surround P− well 21 and source region 28.

Other parasitic devices are prevented by isolation region 16 and guard ring 18. The power transistor formed in active region 20 is isolated from other devices formed on substrate 12 and epitaxial layer 14 by the isolation effects of isolation region 16 and the junction between epitaxial layer 14 and substrate 12. Guard ring 18 prevents the injection of holes into substrate 12 during particular loading and transient conditions for the power transistor. Guard ring 18 generally prevents the formation of vertical PNP current flow from source region 28 to substrate 12, thereby preventing potential latch-up with neighboring devices.

An interlevel dielectric layer 32 is deposited as an insulative structure outwardly from gate insulator layer 22 and gate bodies 24 and 26. Interlevel dielectric layer 32 is approximately 1 micron in thickness. In one embodiment interlevel dielectric layer 32 comprises a silane-based borophosphosilicate glass (BPSG). BPSG films are deposited at low temperatures such as, for example, 400-450° C. and are then immediately densified at approximately 800° C. for one hour. The purpose of this step is to completely stabilize the BPSG films, which would otherwise be prone to blistering during subsequent processing.

Contact openings 34 and 36 may be formed through interlevel dielectric layer 32 and gate insulator layer 22 over source region 28 and drain region 30, respectively. Contact openings 34 and 36 may be formed using a dry etch process.

A reflow process of contact openings 34 and 36 is conducted by exposing device 10 to a high temperature step after the contact openings have been formed. This causes the interlevel dielectric layer 32 to flow slightly, producing rounded corners and sloped sidewalls in openings 34 and 36. For example, BPSG used to comprise interlevel dielectric layer 32 flows at low temperatures (800-850° C. at atmospheric pressures), resulting in rounded corners. Thus, contact openings 34 and 36 are formed from outer surface of inner level dielectric layer 32 down to outer surface of substrate 12 and defined by the rounded corners of interlevel dielectric layer 32.

A conductive interconnect layer 38 is deposited outwardly from interlevel dielectric layer 32. Conductive interconnect layer 38 is approximately 0.75 microns in thickness. Conductive interconnect layer 38 comprises, for example, aluminum or other suitable material. Conductive interconnect layer 38 may also include additional barrier layers or adhesion layers. Conductive interconnect layer 38 is deposited in such a way that it fills contact openings 34 and 36.

An etch process, such as a high energy plasma etch, is preferably used to etch conductive interconnect layer 38 such that source interconnect 40 is formed, contacting source region 28 through contact opening 34, and such that drain interconnect 42 is formed, contacting drain regions 30 through contact opening 36.

A planarization layer 44 is disposed outwardly from conductive interconnect layer 38 forming a planar surface. Planarization layer 44 may be on the order of 1 micron in thickness. Planarization layer 44 may comprise, for example, a deposited oxide. Alternatively, planarization layer 20 may be formed through the process of spin on glass (SOG) planarization. The SOG process combines spin-on glass with a deposited oxide which is deposited through a plasma process. Planarization layer 44 is operable to insulate source interconnect 40 from drain interconnect 42 and all of interconnect layer 38 from subsequent layers of metallization.

A passivation layer 46 is then deposited over the entire top surface of device 10. Passivation layer 46 may be on the order of 1 micron in thickness. Passivation layer 46 prevents mechanical and chemical damage during assembly and packaging. Passivation layer 46 comprises, for example, plasma deposited silicon nitride (Si₃N₄). Silicon nitride is desirable as a material for the formation of passivation layer 46 because it provides an impermeable barrier to moisture and mobile impurities and also forms a tough coat that protects device 10 against scratching. Both passivation layer 46 and planarization layer 44 may be slightly thinner over conductive interconnect layer 38.

The combination of planarization layer 44 and passivation layer 46 provides a relatively defect free means of isolating conductive interconnect layer 38 from subsequent conductive layers such as a drain bus layer 50 disposed over passivation layer 46. For example, the material used in planarization layer 44 and passivation layer 46 can combine to form an insulative structure with excellent thermal stability, low stress, good crack resistance, and high resistance to the penetration of moisture and charged particles. Ideally, these two layers should be thin to allow for adequate heat dissipation. However, counterbalancing this concern is the need to have sufficient insulative thickness to prevent the formation of parasitic capacitances.

A contact opening 48 is formed through passivation layer 46 and planarization layer 44 to drain interconnect 42. Contact opening 48 is aligned/positioned above contact opening 36 and drain region 30. Contact opening 48 may be formed using one or more dry etch processes preferably highly selective to passivation layer 46 and planarization layer 44. Similarly, a contact opening (not shown) is made to source interconnect 40 and bond pad openings (not shown) are made to both source interconnect 40 and drain interconnect 42.

Drain bus layer 50 is formed outwardly from passivation layer 46. Drain bus layer 50 comprises, for example, a conductive metal with low resistivity that can be electrolytically grown, such as copper. Drain bus layer 50 may also comprise additional layers such as titanium tungsten (TiW) adhesion layers.

Drain bus layer 50 may be formed by depositing conductive material so that conductive material fills contact opening 48, contacting drain interconnect 42, and forms a thin layer (not shown) of conductive material overlying passivation layer 46. The thin layer of conductive material is then etched as needed. Following etch, the remainder of the conductive material comprising drain bus layer 50 is then electrolytically grown from the etched initial thin layer of material. A similar source bus layer (not shown) may be formed using similar methods and contacting source interconnect 40 through a similar contact opening (not shown).

In one embodiment, drain bus layer 50 eventually comprises copper of approximately 15 microns in thickness. Copper is highly desirable as a drain bus material because of its very low resistivity. Copper is also a preferred material for bus construction used in power transistors, primarily because of its high current-carrying capability and high thermal conductivity, the latter allowing for enhanced heat dissipation. Copper is desirable over aluminum as a drain bus material because, to obtain the same current carrying capacity, the thickness of the aluminum required makes it difficult to be patterned or etched easily. Copper, on the other hand, can be grown through an electrolytic process as described above, eliminating the need to etch through a full thickness of copper.

The combination of planarization layer 44 and passivation layer 46 effectively isolates drain bus layer 50 from source interconnect 40. It will be understood that drain bus layer 50 may be isolated from source interconnect 40 using only a passivation layer. However, combining planarization layer 44 with passivation layer 46 forms a heterogeneous planarization layer which is relatively defect free, as described above, and retains the properties of isolating drain bus layer 50 from other layers of metallization, and in particular, source interconnect 40.

Although the device of the present invention has been described with reference to the formation of a power MOS transistor device, it should be understood that the use of the isolation technique described herein is equally applicable to the formation of other semiconductor devices. In addition, the combination of a copper interconnect or bus with dielectric isolation can be used to eliminate the necessity for an intermediate conductive layer as described herein. Furthermore, the structure and techniques described above, and more specifically their isolative properties, may be used to simplify a process utilized in the formation of a semiconductor device to more effectively isolate adjacent structures. In particular, it should be noted that the above structure and techniques provides a means for streamlining manufacturing processes by removing the necessity of adding a field oxide layer to isolate a semiconductor structure from a neighboring structure.

Although the present invention has been described in detail, it should be understood that various changes, alterations, substitutions and modifications to the descriptions contained herein may be made without departing from the scope and spirit of the present invention which is solely defined by the appended claims.

What is claimed is:

1. An electronic device comprising:
a substrate having a first conductivity type;
an epitaxial layer having a second conductivity type formed outwardly from the substrate;
an isolation region formed in the epitaxial layer and the substrate;
a guard ring formed in portions of the substrate and portions of the epitaxial layer;
an active region of the second conductivity type formed in the epitaxial layer, the active region defined by the isolation region and the guard ring;
a gate body insulatively disposed outwardly from the active region;
an insulative structure disposed outwardly from the gate body and the epitaxial layer, the insulative structure having a plurality of primary contact openings formed through the insulative structure adjacent to the sides of the gate body;
a conductive interconnect layer disposed outwardly from the insulative structure and filling the primary contact openings, the conductive interconnect layer being etched to form a source interconnect and a drain interconnect;
a planarization layer disposed outwardly from the conductive interconnect layer, the planarization layer having at least one planarization contact opening;
a passivation layer disposed outwardly from the planarization layer, the passivation layer having at least one passivation contact opening located generally over the planarization contact opening;
a conductive layer disposed outwardly from the passivation layer and contacting the conductive interconnect layer through the passivation contact opening and the planarization contact opening; and
wherein the passivation layer and the planarization layer isolate the conductive layer from the source interconnect and drain interconnect of the conductive layer.

2. The electronic device of claim 1, further comprising a source region and a drain region formed in the active region.

3. The electronic device of claim 1, further comprising a P− well formed in the active region.

4. The electronic device of claim 1, wherein the isolation region forms a barrier isolating the electronic device from a neighboring device.

5. The electronic device of claim 1, wherein the guard ring forms a barrier isolating the electronic device from the substrate and a neighboring device.

6. The electronic device of claim 1, wherein the guard ring forms a barrier preventing the formation of vertical pnp parasitic MOS devices between the source and the substrate.

7. The electronic device of claim 2, wherein the gate body completely surrounds the source region, the gate body being operable to form field plating that prevents the formation of parasitic MOS devices.

8. The electronic device of claim 1, wherein the planarization layer comprises spin on glass.

9. The electronic device of claim 1, wherein the passivation layer comprises silicon nitride.

10. The electronic device of claim 1, wherein the exterior conductive layer comprises copper.

11. The electronic device of claim 1, wherein the conductive interconnect layer comprises aluminum.

12. The electronic device of claim 1, wherein the electronic device comprises a power transistor.

13. A method of forming a semiconductor device comprising:
forming a substrate having a first conductivity type;
forming an epitaxial layer having a second conductivity type outwardly from the substrate;
forming an isolation region in the epitaxial layer and the substrate;
forming a guard ring in portions of the underlying region and portions of the second region;
forming an active region of the second conductivity type in the epitaxial layer, the active region defined by the isolation region and the guard ring;
forming a gate body insulatively disposed outwardly from the epitaxial layer;
forming an insulative structure disposed outwardly from the gate body and the epitaxial layer, the insulative structure having a plurality of primary contact openings through the insulative structure adjacent to the sides of the gate body;
forming a conductive interconnect layer outwardly from the insulative structure that fills the primary contact openings, the conductive interconnect layer being etched to form a source interconnect and a drain interconnect;
forming a planarization layer disposed outwardly from the conductive interconnect layer, the planarization layer having at least one planarization contact opening in the planarization layer;
forming a passivation layer disposed outwardly from the planarization layer, the passivation layer having at least one passivation contact opening in the passivation layer located generally over the planarization contact opening; and
forming a conductive layer disposed outwardly from the passivation layer, the conductive layer contacting the conductive interconnect layer through the passivation contact opening and the planarization contact opening.

14. The method of claim 13, further comprising the step of forming a source region and a drain region in the active region.

15. The method of claim 13, further comprising the step of forming a P− well in the active region.

16. The method of claim 14, wherein the step of forming a gate body further comprises surrounding the source region with the gate body, the gate body being operable to form field plating that prevents the formation of parasitic MOS devices.

17. A method of forming a semiconductor device comprising:
forming a substrate having a first conductivity type;
forming an epitaxial layer having a second conductivity type outwardly from the substrate;
forming an isolation region in the epitaxial layer and the substrate;
forming a guard ring in portions of the substrate and portions of the epitaxial layer;
forming an active region of the second conductivity type in the epitaxial layer, the active region defined by the isolation region and the guard ring;
forming a gate insulator layer disposed outwardly from the surface of the active region;
forming a gate body disposed outwardly from the gate insulator layer;
forming a P− well within the active region;
forming a source region and a drain region within the P− well, the gate body completely surrounding the source region;
forming an insulative structure disposed outwardly from the gate body and the epitaxial layer;
forming a plurality of primary contact openings through the insulative structure adjacent to the sides of the gate body;
forming a conductive interconnect layer outwardly from the insulative structure that fills the primary contact openings;
etching the conductive interconnect layer to form a source interconnect and a drain interconnect, the source interconnect contacting the source region through one of the primary contact openings, the drain interconnect contacting the drain region through one of the primary contact openings;
forming a planarization layer disposed outwardly from the conductive interconnect layer;
forming at least one planarization contact opening in the planarization layer;
forming a passivation layer disposed outwardly from the planarization layer;
forming at least one passivation contact opening in the passivation layer located generally over the planarization contact opening; and
forming a conductive layer disposed outwardly from the passivation layer, the passivation layer and the planarization layer isolating the conductive layer from the source interconnect and drain interconnect of the conductive layer, the conductive layer contacting the conductive interconnect layer through the passivation contact opening and the planarization contact opening.

18. The method of claim 17, wherein the step of forming a conductive layer further comprises:
forming a thin layer of conductive material, the thin layer of conductive material filling the passivation contact opening and the planarization contact opening;
etching the thin layer of conductive material to form a conductive bus;
growing additional conductive material from the thin layer of conductive material using an electrolytic process.

19. The method of claim 17, wherein the step of forming a conductive interconnect layer further comprises forming a layer of aluminum.

20. The method of claim 17, wherein the step of forming a conductive layer further comprises forming a layer of copper.
